(19) United States
(12) Patent Application Publication
(10) Pub. No.: US 2012/0327591 A1
(43) Pub. Date: Dec. 27, 2012

(54) RACK SERVER SYSTEM

(75) Inventors: Maw-Zan JAU, Taipei City (TW); Wei-Yi CHU, Taipei City (TW); Chao-Jung CHEN, Taipei City (TW); Tzu-Hung WANG, Keelung City (TW); Chih-Ming CHEN, New Taipei City (TW)

(73) Assignee: Quanta Computer Inc., Tao Yuan Shien (TW)

(21) Appl. No.: 13/368,364

(22) Filed: Feb. 8, 2012

(30) Foreign Application Priority Data
Jun. 21, 2011 (TW) 100121715

(51) Int. Cl. H05K 7/20

(52) U.S. Cl. 361/679.48

(57) ABSTRACT

A rack server system includes a number of server units and a rack. The rack server includes a back plane, a control module, a fan module and a power supply module. The back plane includes a number of slots, via which the server units are respectively connected to the back plane. The fan module is connected to the control module, and dissipates heat generated by the server units under the control of the control module. The power supply module is connected to the control module, and powers the server units under the control of the control module.

This application claims the benefit of Taiwan application Serial No. 100121715, filed Jun. 21, 2011, the subject matter of which is incorporated herein by reference.

### BACKGROUND OF THE INVENTION

1. Field of the Invention

The invention relates in general to a server rack system, and more particularly to a server rack system in which a rack powers, dissipates heat and performs network exchange and miscellaneous management on server units in the server rack system.

2. Description of the Related Art

A conventional blade server, being prevalent in various application situations, in generally disposed in a conventional rack along with many other blade servers to optimize operation conveniences for a user.

In current techniques, blade server units in a conventional rack may be respectively regarded as a full-feature computer. In other words, apart from being equipped with a core (e.g., a central processor, a motherboard, a RAM and a hard disk), each of the blade servers is further provided with peripheral devices including a power supply and a heat dissipation device. However, under application circumstances of a conventional rack, the solution of allocating a power supply and a heat dissipation device in each blade server unit brings complications in management as well as poor heat dissipation efficiency. Therefore, there is a need for an improved solution offering more efficient power supply and heat dissipation for a conventional rack.

### SUMMARY OF THE INVENTION

The invention is directed to a server rack system comprising a rack and a plurality of server units. The rack comprises a back plane comprising a plurality of slots, a fan module, a power supply module and a control module, with the latter three connected to the back plane. The server units are respectively coupled to the back plane via the slots, so that the power supply module powers the server units by providing power supply signals via the back plane and the slots. The fan module dissipates heat generated by the server units under the control of the control unit. Accordingly, compared to a conventional rack system, the server rack system of the present invention, by integrating the fan module and the power supply module in the rack, heat generated by the server units is dissipated and the server units are also powered to correspondingly offer advantages of having better efficiency in heat dissipation as well as in power supply.

According to an aspect the present invention, a server rack system comprising a plurality of server units and a rack is provided. The rack comprises a back plane, a control module, a fan module and a power supply module. The back plane comprises a plurality of slots, via which the server units are respectively connected to the back plane. The fan module is connected to the control module, and dissipates heat generated by the server units under the control of the control module. The power supply module is connected to the control module, and powers the server units under the control of the control unit.

The above and other aspects of the invention will become better understood with regard to the following detailed description of the preferred but non-limiting embodiment. The following description is made with reference to the accompanying drawings.

### BRIEF DESCRIPTION OF THE DRAWINGS

FIG. 1 is a front view of a server rack system according to an embodiment of the present invention.

FIG. 2 is a side view of a server rack system according to an embodiment of the present invention.

FIG. 3 is a rear perspective view of a server rack system according to an embodiment of the present invention.

FIG. 4 is a schematic diagram of a back plane in a rack of a server rack system according to an embodiment of the present invention.

### DETAILED DESCRIPTION OF THE INVENTION

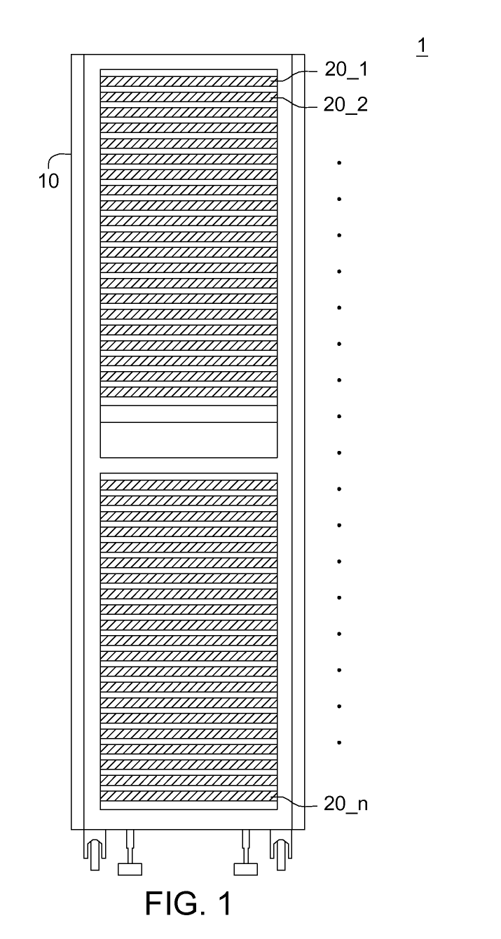

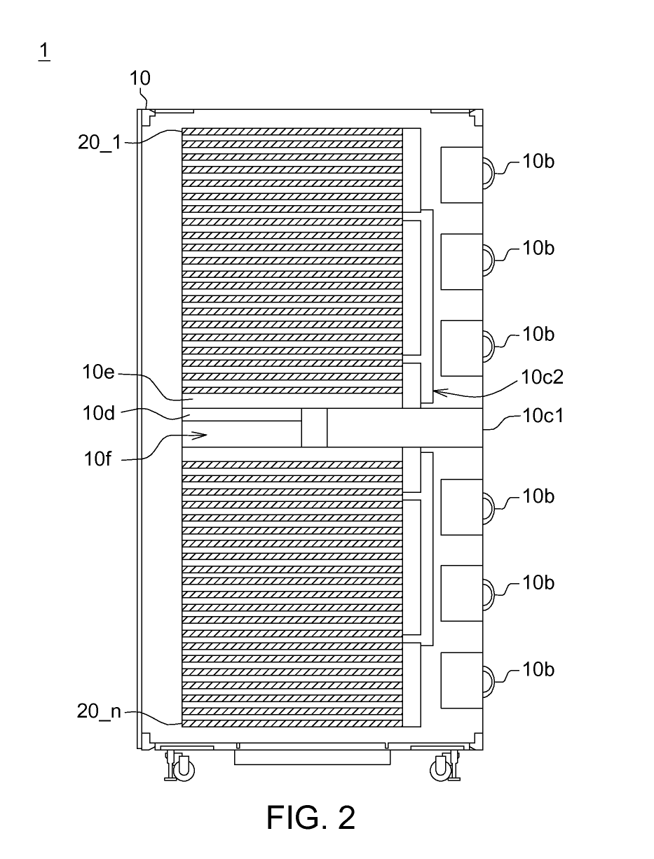

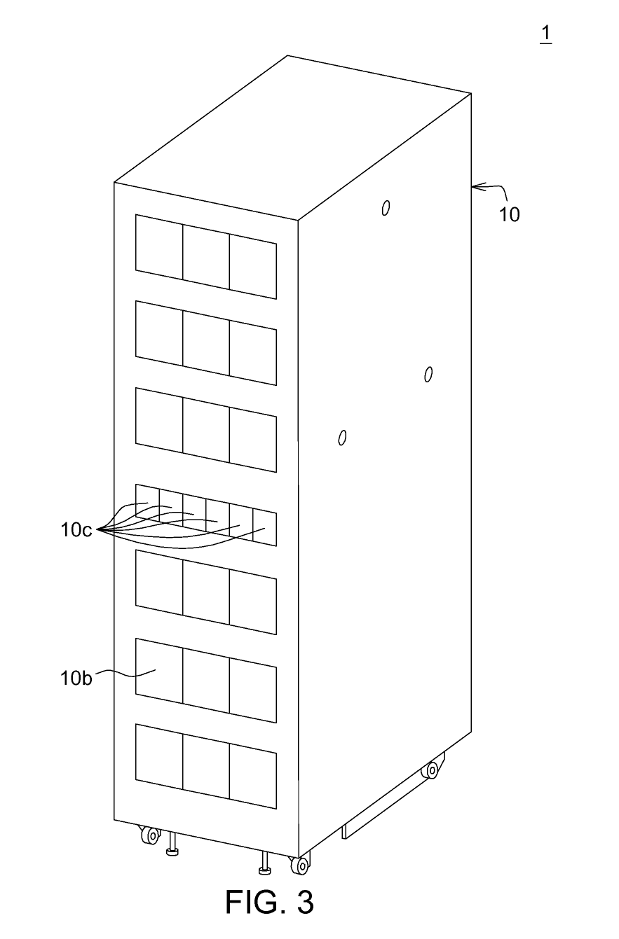

FIGS. 1 to 3 respectively show a front view, a side view and rear perspective view of a server rack system according to an embodiment of the present invention. A server rack system 1 comprises a rack 10 and server units 20_1, 20_2, . . . , 20_{—}n, where n is a natural number greater than 1. For example, the server units 20_1 to 20_{—}n only comprise data processing cores such as a central processor, a motherboard, a RAM and a memory disk, and do not include peripheral devices such as a power supply, a heat dissipation fan and a network controller. In other words, the server units 20_1 to 20_{—}n are incapable of functioning independently outside the server rack system 1.

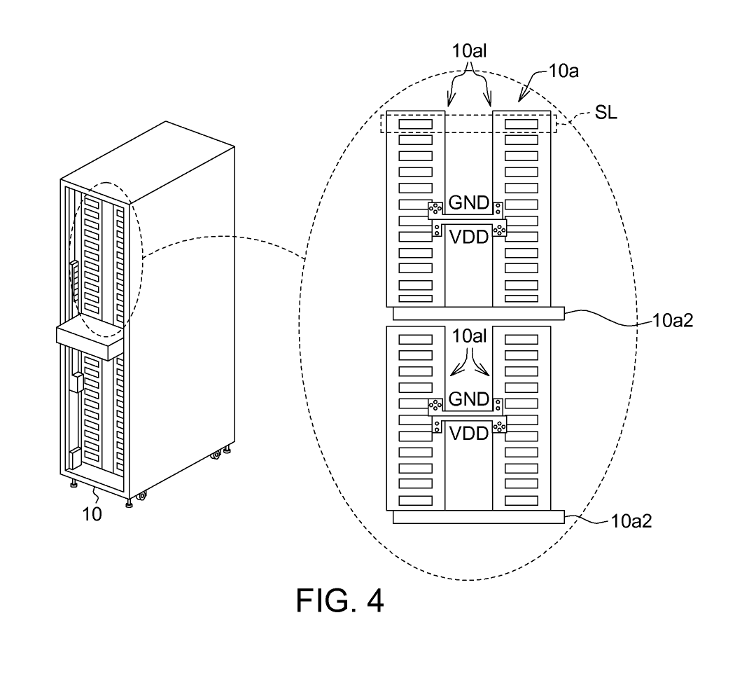

The rack 10 comprises a plurality of server accommodating spaces, in which the server units 20_1 to 20_{—}n are respectively placed. The rack 10 according to the embodiment further comprises a back plane 10 (as shown in FIG. 4), a fan module 10b, a power supply module 10c, and a control module 10d. The back plane 10a is for connecting the server units 20_1 to 20_{—}n, the fan module 10b, the power supply module 10c and the control module 10d. The fan module 10b and the power supply module 10c are respectively controlled by the control module 10d to dissipate heat generated by the server units 20_1 to 20_{—}n and power the server units 20_1 to 20_{—}n. More specifically, the rack 10 according to the embodiment further integrates certain peripheral circuits to provide an operating environment required for normal operations of the server units 20_1 to 20_{—}n accommodated therein.

FIG. 4 shows a schematic diagram of the back plane 10a in the rack 10 of the server rack system 1 according to an embodiment of the present invention. Further, the back plane 10a is disposed at a rear side of the rack 10. For example, the back plane 10a comprises a middle plane board 10a1 and a switch board 10a2. For example, the middle plane board 10a1 comprises power contacts for receiving a high-level reference voltage VDD and a ground reference voltage GND to accordingly provide the high-level reference voltage VDD and the ground reference voltage GND to the server units 20_1 to 20_{—}n.

The middle plane board 10a1 further comprises a plurality of slots (as indicated by slots SL in FIG. 4), via which the server units 20_1 to 20n are connected to the middle plane board 10a1 by hot swapping. For example, each of the server units 20_1 to 20_{—}n comprises an interposer board structure, which is connected to the middle plane board 10a1 via a Peripheral Component Interconnect Express (PCI-E) connector.

For example, the switch board 10a2 is an inter integrated circuit (I²C) switch board that is connected to the control module 10d via an I²C bus. The switch board 10a2 is further connected to the middle plane board 10a1, so that the control module 10d is allowed to control the server units 20_1 to 20_{—}n at the middle plane board 10a1 via the I²C bus.

For example, the fan module 10b is connected to the control module 10d via the switch board 10a2, and dissipates heat generated by the server units 20_1 to 20_{—}n under the control of the control unit 10d.

For example, the power supply module 10c comprises a power circuit 10c1 and a power distribution board (PDB) 10c2. For example, the power circuit 10c1 receives a commercial electricity signal to provide an input power signal. For example, the PDB 10c2 is connected to the control module 10d via a DB25 cable, and provides power signals according to the input power signal to power the server units 20_1 to 20n.

In an embodiment, the rack 10 further comprises an uninterruptible power supply (UPS) module 10e coupled the power circuit 10c1. The UPS module 10e detects whether an abnormal event (e.g., a sudden power off) occurs in the input power signal. When an abnormal event occurs in the input power signal, the UPS module 10e provides auxiliary power signals to power the server units 20_1 to 20n. That is, the USP module 10e powers the server units 20_1 to 20_{—}n when the input power signal is abnormal. For example, the UPS module 10e comprises a battery circuit (not shown), which performs charging in response to the input power signal, and provides the auxiliary power signals to power the server units 20_1 to 20_{—}n when an abnormal event occurs in the input power signal.

In an embodiment, the rack 10 further comprises a network exchange module 10f connected to the control module 10d. The network exchange module 10f performs network communication exchange on the server units 20_1 to 20_{—}n.

In this embodiment, it is to be understood that the server rack system 1 comprising circuit configurations as shown in FIGS. 1 to 3 is taken as an example for illustrations rather than limiting the present invention thereto. In other examples, the server rack system according to this embodiment may adjust the number of the server units accommodated therein based on actual application situations. Further, the fan module and the power supply module may also be selectively allocated at other physical locations.

In the server rack system comprising a rack and a plurality of server units according to the embodiment of the present invention, the rack comprises a back plane comprising a plurality of slots, a fan module, a power supply module and a control module, with the latter three connected to the back plane. The server units are respectively coupled to the back plane via the slots, so that the power supply module powers the server units by providing power supply signals via the back plane and the slots. The fan module dissipates heat generated by the server units under the control of the control unit. Accordingly, compared to a conventional rack system, the server rack system of the present invention, by integrating the fan module and the power supply module in the rack, heat generated by the server units is dissipated and the server units are also powered to correspondingly offer advantages of having better efficiency in heat dissipation as well as in power supply.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A server rack system, comprising:
a plurality of server units; and
a server, comprising:
a back plane, comprising a plurality of slots, via which the server units being respectively connected to the back plane;
a control module;
a fan module, connected to the control module, for dissipating heat generated by the server units under a control of the control module; and
a power supply module, connected to the control module, for powering the server units under the control of the control module.

2. The server rack system according to claim 1, wherein the back plane further comprises:
a switch board, connected to the control module via a bus and connected to the fan module via a fan control bus, the fan module being controlled by the control module via the switch board.

3. The server rack system according to claim 2, wherein the bus is an inter integrated circuit (I²C) bus.

4. The server rack system according to claim 1, wherein the power supply module comprises:
a power circuit, for providing an input power signal; and
a power distribution board (PDB), connected to the control module via a bus and being controlled by the control module, for providing a plurality of power signals according to the input power signal to power the server units.

5. The server rack system according to claim 1, wherein the rack further comprises:
an uninterruptible power supply (UPS) module, for detecting whether an abnormal event occurs in the input power signal, and providing a plurality of auxiliary power signals to power the server units when the abnormal event occurs in the input power signal.

6. The server rack system according to claim 2, wherein the UPS module further comprises:
a battery circuit, for performing charging in response to the input power signal, and providing the auxiliary power signals when the abnormal event occurs in the input power signal.

7. The server rack system according to claim 1, further comprising:
a network exchange module, connected to the control module, for performing network communication exchange on the server units.
